(19) United States
(12) Patent Application Publication
(10) Pub. No.: US 2008/0126001 A1
(43) Pub. Date: May 29, 2008

(54) Equipment testing system and method having scaleable test line limits

(76) Inventors: David W. Murray, Windsor, CA (US); Kim Chung Thi Thanh, Rohnert Park, CA (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/515,258

(22) Filed: Sep. 1, 2006

(51) Int. Cl. G06F 19/00; G06F 15/00; G01R 31/02

(52) U.S. Cl. 702/119; 702/185

(57) ABSTRACT

A method is provided for performing a diagnostic test of a piece of equipment, the equipment including a plurality of components and an embedded diagnostic tool, each component including a respective fault report store. The method comprises setting initial test limits; running a diagnostic test; testing whether the test limits need to be re-scaled, and if so, then (i) re-scaling the test limits, and (ii) re-running the diagnostic test.

### BACKGROUND OF THE INVENTION

The present invention relates to diagnostic testing for electronic equipment.

Conventional diagnostic testing arrangements have involved coupling a test system, such as a production line Unix workstation, to an instrument or piece of equipment to be tested. Troubleshooting software applications, in the form of BASIC or C language programs or shell scripts, etc., reside within the test system.

When such troubleshooting software applications are executed, the test system, and the instrument to be tested, communicate through a communication interface. For instance, many such troubleshooting applications use an IEEE 488 General Purpose Interface Bus (GPIB) connection between the UNIX workstation and the instrument.

It would be advantageous to employ standard network communications for such diagnostic testing, obviating the need for a diagnostic-specific interface such as the GPIB and allowing for remote testing. It would also be advantageous to execute diagnostic testing on-board the equipment to be tested.

### SUMMARY OF THE INVENTION

A method is provided for performing a diagnostic test of a piece of equipment, the equipment including a plurality of components and an embedded diagnostic tool, each component including a respective fault report store. The method comprises setting initial test limits; running a diagnostic test; testing whether the test limits need to be re-scaled, and if so, then (i) re-scaling the test limits, and (ii) re-running the diagnostic test.

Further features and advantages of the present invention, as well as the structure and operation of preferred embodiments of the present invention, are described in detail below with reference to the accompanying exemplary drawings.

### BRIEF DESCRIPTION OF THE DRAWINGS

FIGS. 1 and 2 are block diagrams illustrating a system for performing embedded diagnostic tests on a piece of equipment containing an embodiment of the invention.

FIGS. 3 and 4 are flowcharts showing operation of an embodiment of the invention.

### DETAILED DESCRIPTION

A system embodying the invention includes self-contained embedded diagnostics for a piece of electronic equipment. Among other fields, such a system may be employed in a measurement apparatus for radiofrequency (hereinafter “RF”) systems.

Initial testing of factory-manufactured equipment before shipment to the user/customer may easily be performed. However, once a piece of equipment leaves the factory and a user begins using it, it is notoriously difficult to receive good failure data from the field. In such systems, it is desirable to be able to self-diagnose problems which can be solved by replacing components of the equipment, such as sub-assemblies, cables, etc., without requiring the use of external test and measurement equipment. When such a problem is diagnosed, service personnel not necessarily requiring great expertise or training, can replace the faulty component.

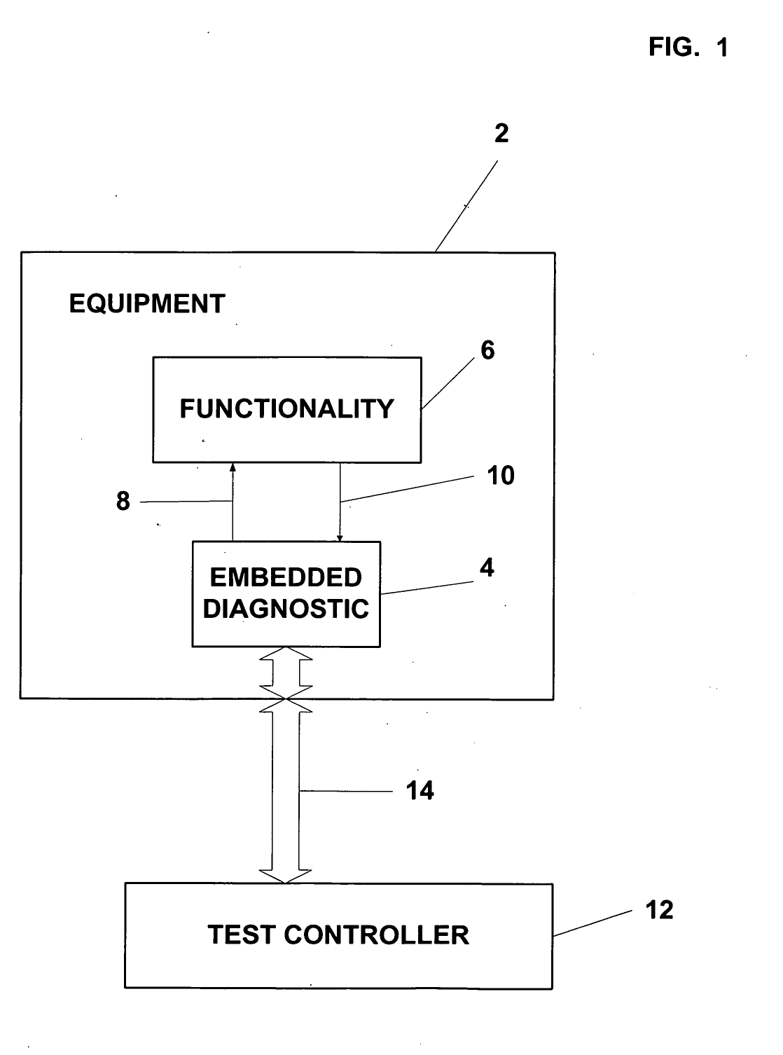

For instance, FIG. 1 is a schematic block diagram of a system in which a piece of equipment 2, which is to be tested, includes an embedded diagnostic apparatus 4. The equipment 2 has a general functionality 6, whose nature is not essential to the present invention but is characteristic of the type of equipment 2. The diagnostic apparatus 4 provides input stimulus signals to the functionality 6 through an input 8, and receives response signals through an output 10.

The diagnostic apparatus 4 is operated by means of a diagnostic test comment, which may be entered by an equipment operator through a user interface (not shown) of the equipment 2. Alternatively, the diagnostic 4 can be controlled by either an on-board automatic diagnostic test scheduler (not shown separately, but part of the test apparatus 4), or an external test controller 12, through a communication link 14.

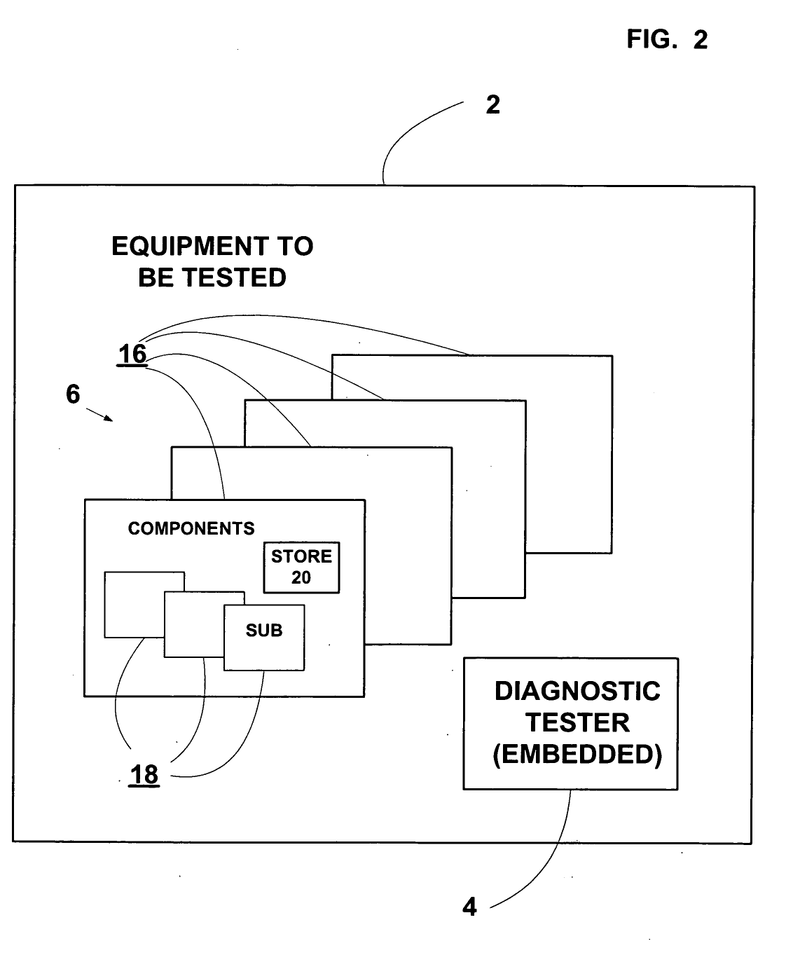

In FIG. 2, the equipment 2 is shown in more detail, with its functionality 6 comprising a variety of components, shown collectively and schematically as 16. The components 16 are made up of sub-components which, in the example of one of the components 16, are shown collectively and schematically as 18. The components 8, and their respective subcomponents 18, have various structures and functions suitable for the particular nature of the equipment 2.

Additionally, each component 16 contains a diagnostic test fault report store 20, such as an electrically erasable programmable read-only memory (EEPROM). As will be described in detail below, diagnostic test results are stored in the fault report store 20.

In the discussion which follows, the term “indicted” will be used to describe a component, sub-assembly, etc., of the equipment 2, for which a problem has been diagnosed. Also, the terms “component” and “communication component” will be used interchangeably, to refer broadly and without limitation to any sub-assembly, cable, interface, component, etc., within a communications system, for which a fault may occur. The term “fault” will refer to any problem that is, or can be, isolated within a particular component of the communication system. Finally, the terms “instrument” and “device under test” (or “DUT”) will be used to refer to the equipment 2 to be tested.

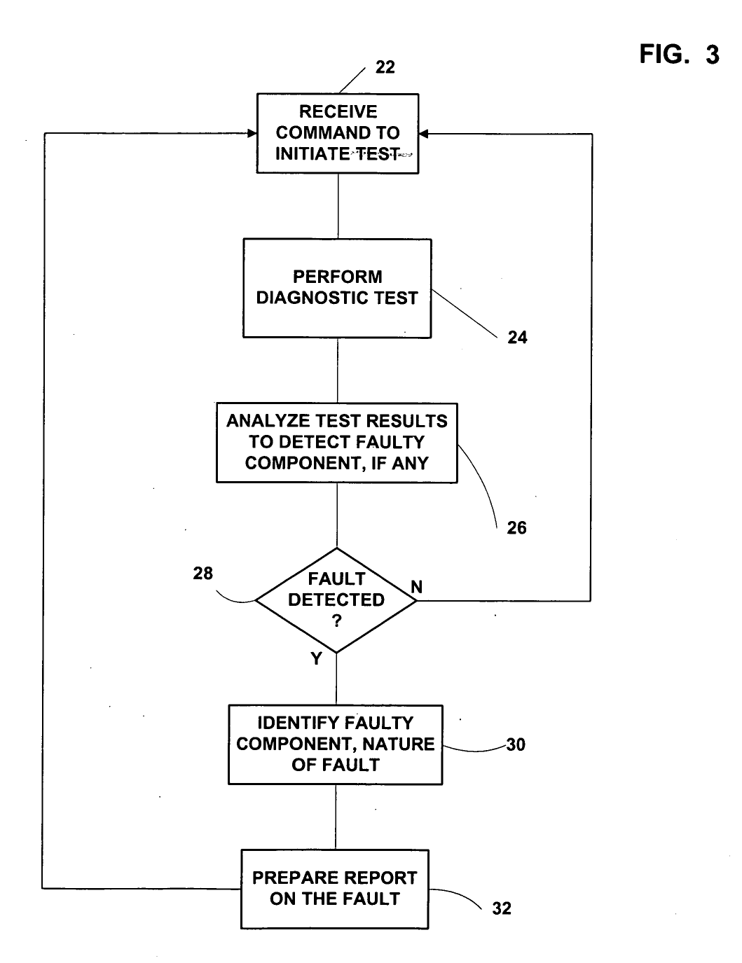

FIG. 3 is a flowchart, showing a basic process for performing a diagnostic test on a piece of equipment containing an embedded diagnostic apparatus embodying the invention, generally as illustrated in FIGS. 1 and 2.

Initially, a test command is received (22). Such a command can come from a user input interface on the equipment itself, via a remote command received over a network or other communication line coupled to the equipment, or from an automatic test scheduling and control apparatus.

Responsive to the test command, the test controller initiates and performs the test (24), such as by sending a test signal through a communication pathway of the functionality 6. The test controller then monitors the functioning of the equipment 2, such as by monitoring various test points and observing the signals present there, to detect and obtain test information regarding how the various components 16 of the equipment 2, along the communication pathway, are behaving. The detected test information is analyzed (26) to determine whether the equipment 2 and its components 16 are functioning normally, or whether an abnormality that may be indicative of a fault or problem has been detected.

Based on that analysis, it is determined (28) first, whether a fault has been detected, and second, based on which test points show which abnormalities, which component seems to be faulty. If no fault is detected, the test apparatus idles or performs other functions until another test command (22) is received.

If a fault is detected, a faulty one of the components 16, and the nature of the fault, are analyzed and reported to the system operator (32), through a user interface, printer, display, etc. A fault report is prepared. The report is stored in the fault report store 20, and/or displayed or printed to the system operator, through a user interface, printer, display, etc. The report may also be transmitted to the remote test controller 12. The report is in a form that will direct the operator to replace the component believed to be faulty. Where an operator does not necessarily have great expertise with the equipment but has facility with swapping components in and out, the report is sufficient to enable the operator to take action that will enable the equipment 2 to keep on functioning.

In addition to the diagnostic process summarized in FIG. 3, there is a further function related to the analysis (26). Based on the results of the analysis, it is possible to calibrate the equipment. Once the calibration is done, running further diagnostic tests, or re-running the same diagnostic test as before, can improve the diagnostic's assessment of the equipment's functioning. For instance, a diagnostic at the first level of calibration might not detect a fault, but after running the diagnostic the first time and refining the equipment's calibration, re-running the diagnostic a second time might identify a latent fault. As an instrument proceeds through our final test process gaining more calibration, the expectation on its performance also increases.

In one embodiment of the diagnostic testing method of the invention, testing becomes more specific as the device under test moves through tests, or iterations of the tests. That is, the test line limits are changed, to become more stringent, in such successive tests or iterations. As the calibration improves with successive, more stringent iterations, the performance of the equipment conforms more and more closely with a predetermined optimum performance. Pieces of equipment that are iteratively calibrated and conform closely with the predetermined optimum performance become increasingly interchangeable and identical in performance. As a result, different systems, which employ the same make and model of equipment so calibrated, function in an increasingly consistent manner.

For instance, in an embedded diagnostic system and method for RF measurement equipment, certain tests such as flatness (i.e., amplitude vs. frequency correction data) also become naturally more accurate as the instrument receives more calibration. A given system test is used in a series of iterations, with a successively different test limits. The test limit changes depend on which ordinally-numbered iteration (i.e., the first iteration, the fourth iteration, etc.) in the series of iterations the instrument is being tested.

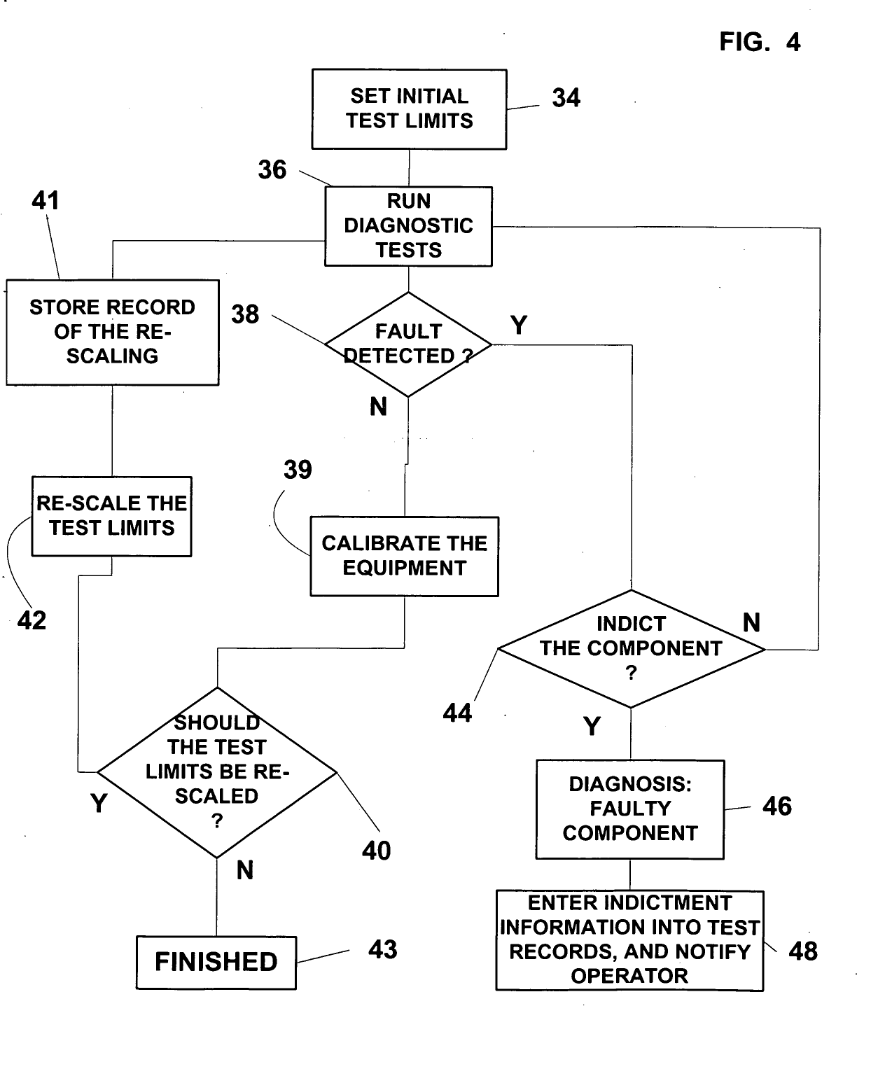

FIG. 4 is a more detailed flowchart, showing additional aspects of an embodiment of the invention. Prior to execution of a diagnostic test such as that shown in FIG. 3, test limits are set (34) to an initial set of values.

A diagnostic test is run and the results are analyzed (36), similarly to that described in FIG. 3 (24) and (26). A test for whether a fault has been detected is performed (38), similarly to that of FIG. 3 (28).

Assuming that a fault is not detected at (38), the equipment is then calibrated (39) using the test results. Such calibration will tend to improve the performance of the equipment. Also, however, the calibration of (39) may increase the sensitivity of the equipment to faults. Thus, a test is made (40), for whether the test limits, initially set in (34), should be re-scaled. If so, the test limits are re-scaled (42), a record of the re-scaling is stored (41), and then an additional set of diagnostic tests, or a repetition of the test already performed, may be performed (36).

The process of testing, equipment calibration, test limit re-scaling, and re-testing may be performed iteratively, a plurality of times. Eventually, it is decided that there is no further need for re-scaling (40) and (42), and the diagnostic test procedure is finished (43).

On the other hand, due to the improved calibration and the re-scaled test limits, there may be an iteration at which a fault is detected (38) within a component of the equipment. Then, a decision is made whether the component is to be indicted (44). If there are extenuating reasons why the component should not be indicted, then further diagnostics may be run (36), or other tasks unrelated to the diagnostic testing may be performed.

If the faulty component is to be indicted, then a diagnosis of a faulty component is made (46). This may include diagnosis of a sub-component of the faulty component, within which the fault is deemed likely to exist. A fault report (including indictment information) is prepared (48) and stored in the faulty component's fault report store. Also, the equipment operator is notified, so that the operator can replace the faulty component or take other appropriate action.

The portion of the method of FIG. 4 relating to re-scaling the test limits may be implemented as follows:

At each iteration or stage of the above-described test process, a value is ascertained, which represents the expected performance at the process stage. The value is stored (41), such as by writing it into a calibration file maintained as part of the diagnostic test apparatus 4.

In a subsequent iteration or stage, the stored value is read back out, and used to derive the re-scaled testing limits (42) for the upcoming process iteration or stage. It is also used for calibrating (39) the equipment 2.

After the final iteration or stage, performance expectations (including calibration of the instrument 2) will have reached a maximum (i.e., maximum conformity with an optimum), therefore the instrument 2 ships with the tightest specifications.

Systems and methods for scaling test line limits, as described above, could also apply to hardware options or software measurement algorithms like noise reduction.

Although the present invention has been described in detail with reference to particular embodiments, persons possessing ordinary skill in the art to which this invention pertains will appreciate that various modifications and enhancements may be made without departing from the spirit and scope of the claims that follow.

1. A method for performing a diagnostic test of a piece of equipment, the equipment including a plurality of components and an embedded diagnostic tool, each component including a respective fault report store, the method comprising:
setting initial test limits;
running a diagnostic test;
testing whether the test limits need to be re-scaled;
if so, then (i) re-scaling the test limits, and (ii) re-running the diagnostic test.

2. A method as recited in claim 1, further comprising, if the test limits need to be re-scaled, calibrating the piece of equipment based on the test results.

3. A method as recited in claim 1, further comprising diagnosing a faulty component of the equipment based on results of the diagnostic test.

4. A method as recited in claim 1 further comprising storing a record of results of the re-scaling the test limits.

5. A method as recited in claim 4, wherein running a diagnostic test includes:
reading the stored record of results of the re-scaling the test limits;
setting test limits based on the stored record; and
running a diagnostic test using the set test limits.

6. A piece of equipment that includes an embedded diagnostic apparatus, the embedded diagnostic apparatus comprising:
an embedded diagnostic tester; and
a diagnostic test fault report store associated with a component of the piece of equipment, for storing diagnostic test results pertaining to the associated component;
the embedded diagnostic tester including means for:
(i) responsive to a test command, initiating and performing a test for the piece of equipment;
(ii) monitoring the functioning of the piece of equipment;
(iii) detecting and obtaining test information;
(iv) analyzing the test information to determine whether the piece of the equipment and the associated component are functioning normally;
(v) determining whether a fault has been detected and if so whether the associated component seems to be faulty; and
(vi) if the associated component seems to be faulty, preparing a fault report and storing the fault report in the diagnostic test fault report store of the associated component.

7. A piece of equipment as recited in claim 6, wherein the test command is received from one of:
(i) a user input interface of the piece of equipment;
(ii) a communication line coupled to the piece of equipment; and
(iii) an automatic test scheduling and control apparatus.

8. A piece of equipment as recited in claim 6, wherein the embedded diagnostic tester further includes one of:
means for transmitting the fault report to a remote test controller; and
means for providing the fault report to a system operator through one of (i) a a user interface display, and (ii) a printer.

9. A piece of equipment as recited in claim 6, wherein the embedded diagnostic tester further includes:
means for calibrating the piece of equipment based on the analysis of the test information; and
repeating the performing, monitoring, detecting and obtaining, and analyzing based on the calibration.
